(19) United States
(12) Patent Application Publication
(10) Pub. No.: US 2014/0057411 A1
(43) Pub. Date: Feb. 27, 2014

(54) DICING BEFORE GRINDING AFTER COATING

(71) Applicant: HENKEL US IP LLC, Rocky Hill, CT (US)

(72) Inventors: Gina Hoang, Garden Grove, CA (US); YounSang Kim, Irvine, CA (US); Rosette Guino, Irvine, CA (US); Qiaohong Huang, Trabuco Canyon, CA (US)

(73) Assignee: HENKEL US IP LLC, Rocky Hill, CT (US)

(21) Appl. No.: 14/068,339

(22) Filed: Oct. 31, 2013

Related U.S. Application Data
(63) Continuation of application No. PCT/US2012/048111, filed on Jul. 25, 2012.
(60) Provisional application No. 61/513,146, filed on Jul. 29, 2011.

(51) Int. Cl. H01L 21/78

(52) U.S. Cl. CPC H01L 21/78
USPC 438/460

(57) ABSTRACT

This invention is a method for singulating a semiconductor wafer into individual semiconductor dies, the top surface of the semiconductor wafer bumped with metallic pre-connections and having a coating of underfill disposed over and around the metallic pre-connection bumps. The method comprises (A) providing a semiconductor wafer having a top surface with an array of metallic pre-connection bumps and a coating of underfill disposed over and around the metallic pre-connection bumps; (B) dicing through the underfill between the metallic pre-connection bumps and into the top surface of the semiconductor wafer to the ultimate desired wafer thickness, creating dicing lines; and (C) removing wafer material from the backside of the wafer at least to the depth of the dicing lines, thus singulating the resulting dies from the wafer.

### BACKGROUND OF THE INVENTION

This invention relates to a method of fabricating a semiconductor wafer with applied underfill encapsulant.

Miniaturization and slimming of electrical and electronic equipment has led to a need for both thinner semiconductor devices and thinner semiconductor packaging.

A way to produce a thinner semiconductor die is to remove excess material from the back side of the semiconductor wafer from which the individual dies are diced. The removal of the excess wafer typically occurs in a grinding process, commonly called back side grinding. When the wafer is diced into individual semiconductor circuits before the wafer is thinned, the process is called “dicing before grinding” or DBG.

A way to produce smaller and more efficient semiconductor packages is to utilize a package having an array of metallic bumps attached to the active face of the package. The metallic bumps are disposed to register with bonding pads on a substrate. When the metallic bumps are reflowed to a melt, the bumps connect with the bonding pads forming both electrical and mechanical connections.

A thermal mismatch exists among the wafer material, the metallic bumps, and the substrate, causing the metallic interconnections to be stressed with repeated thermal cycling. This can lead potentially to failure. To counteract this, an encapsulating material, called an underfill, is disposed in the gap surrounding and supporting the metallic bumps, between the wafer and the substrate.

Current trends in semiconductor packaging fabrication favor completing as many process steps as possible at the wafer level, allowing multiple integrated circuits to be processed at the same time, rather than individually, as occurs after die singulation. Applying underfill encapsulant over the array of metallic bumps and wafer circuitry before dicing the wafer into individual semiconductor dies is one of the operations performed at the wafer level.

In a typical process, a semiconductor wafer bumped with metallic pre-connections is coated with an underfill material over the metallic bumps. A support tape, called a back grinding tape is laminated over the underfill material on the top side of the wafer. Wafer material from the backside of the wafer is removed by grinding or other means. The back grinding tape is removed from the underfill on the top side of the wafer. A dicing tape is applied to the backside of the wafer to support the wafer during dicing, which follows. Dicing can be done by laser, which is costly, or it can be done mechanically by a dicing blade. Because the thinned wafer is particularly fragile, the use of a dicing blade, although less expensive, can cause damage to the wafer, the circuitry, and the underfill.

This creates a need for a process for singulating a semiconductor wafer into individual semiconductor dies in which the underfill can be pre-applied, but in which a mechanical dicing operation does not damage the bumped wafer and underfill.

### SUMMARY OF THE INVENTION

This invention is a method for singulating a semiconductor wafer into individual semiconductor dies, the top surface of the semiconductor wafer bumped with metallic pre-connections and having a coating of underfill disposed over and around the metallic pre-connection bumps.

The method comprises (A) providing a semiconductor wafer having a top surface with an array of metallic pre-connection bumps and a coating of underfill disposed over and around the metallic pre-connection bumps; (B) dicing through the underfill between the metallic pre-connection bumps and into the top surface of the semiconductor wafer to the ultimate desired wafer thickness, creating dicing lines; and (C) removing wafer material from the backside of the wafer to the depth of the dicing lines, thus singulating the resulting dies from the wafer.

### BRIEF DESCRIPTION OF THE DRAWINGS

FIG. 1 is a schematic of a prior art process for singulating a wafer with a pre-applied underfill material.

FIG. 2 is a schematic of the inventive process for singulating a wafer with a pre-applied underfill material.

### DETAILED DESCRIPTION OF THE INVENTION

The semiconductor wafer is prepared from a semiconductor material, typically silicon, gallium arsenide, germanium, or similar compound semiconductor materials. The active circuitry and metallic bumps on the top side of the wafer are made according to semiconductor and metallic fabrication methods well documented in industry literature.

A dicing tape is typically used to support the wafer during dicing operations. Dicing tapes are commercially available from a number of sources and can be in the form of a heat sensitive, pressure sensitive, or UV sensitive adhesive on a carrier. The carrier is typically a flexible substrate of polyolefin or polyimide. When heat, pulling stress, or UV is applied respectively, the adhesiveness decreases. Commonly, a release liner covers the adhesive layer and can be easily removed just prior to use of the dicing tape. In the DBG process, the dicing tape is applied to the back side of the wafer and dicing grooves are cut between the circuits on the top side of the wafer to a depth that will meet or pass the level to which the back side grinding will be done.

A back grinding tape is used to protect and support the metallic bumps and top surface of the wafer during the wafer thinning process. Back grinding tapes are commercially available from a number of sources and in one form consist of a heat sensitive, pressure sensitive, or UV sensitive adhesive on a carrier. The carrier is typically a flexible substrate of polyolefin or polyimide. When heat, pulling stress, or UV is applied respectively, the adhesiveness decreases. Commonly, a release liner covers the adhesive layer and can be easily removed just prior to use of the back grinding tape. The back grinding operation may be performed by mechanical grinding or etching. The material on the back side of the wafer is removed until the dicing grooves are reached or beyond, which singulates the dies.

Underfill encapsulant typically is applied in paste or film form. The paste can be applied by spray, spin coating, stenciling, or any of the methods used in the industry. Underfill in the form of a film is frequently preferred because it is less messy and easier to apply in a uniform thickness. Adhesives and encapsulants suitable as underfill chemistry that can be in the form of films are known, as are methods for making the films themselves. The thickness of the underfill material can be adjusted so that the metallic bumps can be either completely or only partially covered after lamination. In either case, the underfill material is supplied so that it fully fills the space between the semiconductor and the intended substrate.

In one embodiment, the underfill material is provided on a carrier and is protected with a release liner. Thus, the underfill material in one version is provided in a three layer form in which the first layer is a carrier, such as a flexible polyolefin or polyimide tape, the second layer is the underfill material, and the third layer is a release liner, in that order. Just before use, the release liner is removed and the underfill is typically applied when still attached to the carrier. After application of the underfill to the wafer, the carrier is removed.

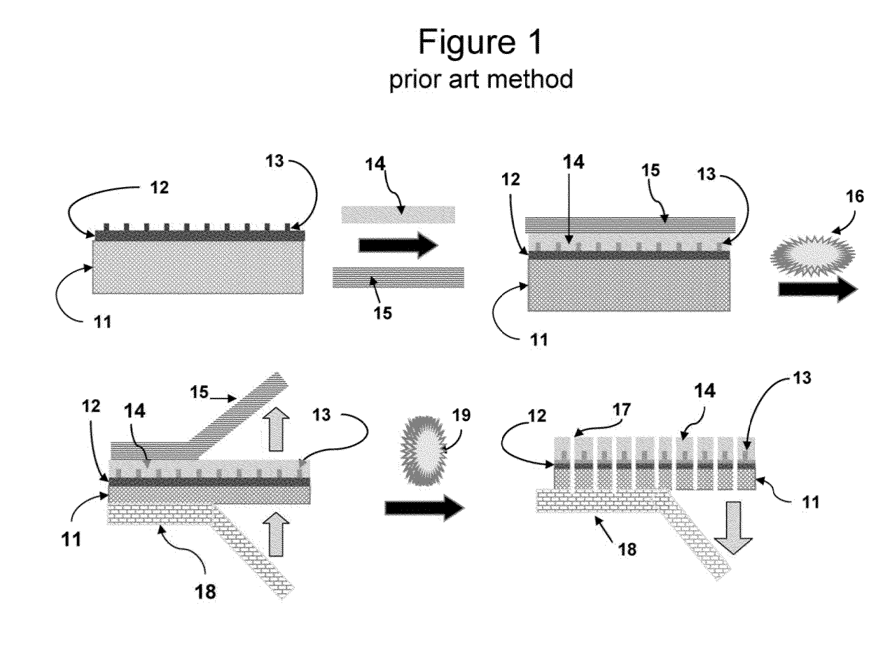

The invention will be further described in reference to the figures. FIG. 1 shows a prior art method of dicing a silicon wafer 11 having active circuitry 12 and an array of metallic bumps 13 on one surface. The active circuitry and metallic bumps are first encapsulated with an underfill material 14. A back grinding tape 15 is laminated to the underfill 14 to support the wafer and protect the underfill, after which the backside of the wafer is reduced in thickness by a grinding blade 16 or any other appropriate method selected by the practitioner.

After back grinding, a dicing tape 18 is applied to the back side of the wafer to support the wafer and keep the dies in place during dicing and after dicing occurs. The back grinding tape 15 is removed from the wafer and a dicing blade 19 is used to cut dicing trenches, also called dicing lines, through the underfill and into the wafer in spaces around the active circuitry to singulate the circuitry into individual dies. Element 17 represents the dicing lines and ultimately the space between the individual semiconductors after dicing and singulation. When the wafer is thinned during back grinding, it becomes very fragile and the active circuitry can be damaged during the dicing operation by the mechanical stress of the cutting blade. To compensate for this, cutting speeds are reduced. The damage to active circuitry and reduction in cutting speeds lower manufacturing through-put and increase cost.

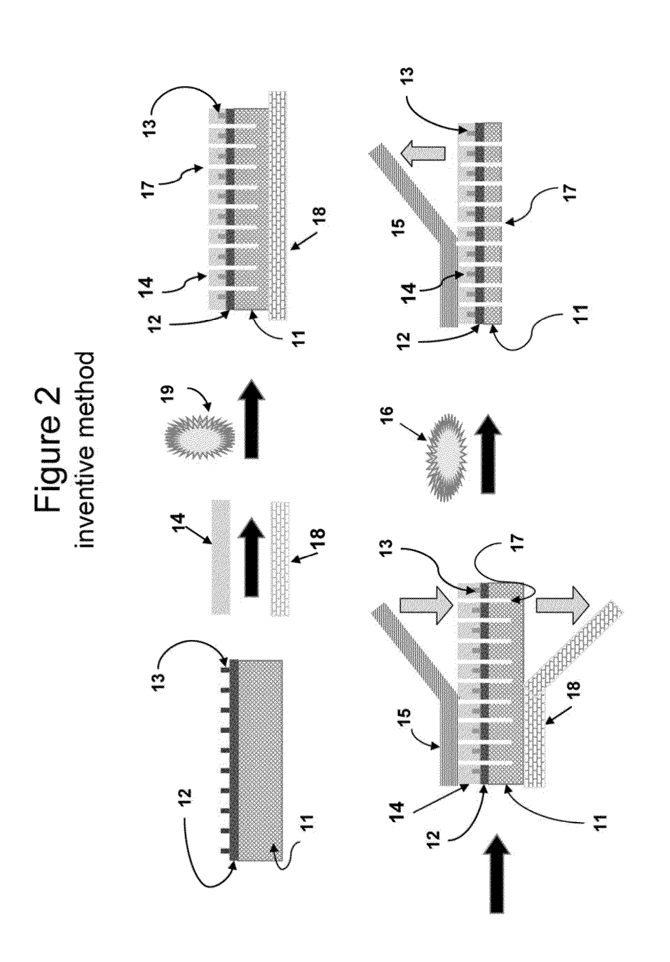

The inventive method, in which dicing occurs after underfill encapsulation and before grinding, is depicted in FIG. 2. A silicon wafer 11, having active circuitry 12 and an array of metallic bumps 13, is provided; the active circuitry and metallic bumps are encapsulated with an underfill material 14. The wafer is mounted on a dicing tape 18 with the back side of the wafer in contact with the dicing tape. A dicing blade 19 cuts through the underfill and into the wafer in spaces around the active circuitry creating dicing lines 17. After singulation, element 17 represents the space between the individual semiconductors. The dicing lines are cut into the wafer to the depth desired for the ultimate thickness of the wafer, or beyond. A back grinding tape 15 is laminated to the underfill on the top side of the wafer and the dicing tape 18 is removed from the back side of the wafer. The back side of the wafer is then is reduced in thickness, such as by grinding with a grinding blade 19, or by any other appropriate method selected by the practitioner. The reduction in thickness is taken at least to the depth of the dicing lines, and can be taken further to whatever final thickness of the wafer is desired. By removing thickness from the back side of the wafer at least to the depth of the dicing lines, the wafer is singulated into individual dies.

1. A method for singulating a semiconductor wafer into individual semiconductor dies, the top surface of the semiconductor wafer bumped with metallic pre-connections and having a coating of underfill disposed over and around the metallic pre-connection bumps, the method comprising:
(A) providing a semiconductor wafer having a top surface with an array of metallic pre-connection bumps and a coating of underfill disposed over and around the metallic pre-connection bumps;
(B) dicing through the underfill between the metallic pre-connection bumps and into the top surface of the semiconductor wafer to the ultimate desired wafer thickness, creating dicing lines; and
(C) removing wafer material from the backside of the wafer at least to the depth of the dicing lines, thereby singulating the resulting dies from the wafer.
